(19) United States
(12) Patent Application Publication
(10) Pub. No.: US 2025/0286563 A1
(43) Pub. Date: Sep. 11, 2025

(54) HIGH-SPEED PARALLEL-TO-SERIAL CONVERSION CIRCUIT

(71) Applicant: Chongqing GigaChip Technology Co., Ltd., Chongqing (CN)

(72) Inventors: Fayan ZENG, Chongqing (CN); Xuying ZHANG, Chongqing (CN); Lei ZHANG, Chongqing (CN); Mingyuan XU, Chongqing (CN); Wei SUN, Chongqing (CN); Fangning LI, Chongqing (CN); Yubin YOU, Chongqing (CN); XiaoFeng SHEN, Chongqing (CN); Can ZHU, Chongqing (CN)

(73) Assignee: Chongqing GigaChip Technology Co., Ltd., Chongqing (CN)

(21) Appl. No.: 19/218,663

(22) Filed: May 27, 2025

Related U.S. Application Data
(63) Continuation of application No. PCT/CN2022/139050, filed on Dec. 14, 2022.

(30) Foreign Application Priority Data
Nov. 30, 2022 (CN) 202211528780.8

(51) Int. Cl. H03M 9/00

(52) U.S. Cl. CPC H03M 9/00

(57) ABSTRACT

A high-speed parallel-to-serial conversion circuit includes a clock frequency division module, a low-speed CMOS parallel-to-serial conversion module, and a high-speed bipolar parallel-to-serial conversion module. The low-speed CMOS parallel-to-serial conversion module includes N1 stages of CMOS parallel-to-serial conversion units which are cascaded in sequence and present a tree structure, and the high-speed bipolar parallel-to-serial conversion module includes N2 stages of bipolar parallel-to-serial conversion units which are cascaded in sequence and present a tree structure.

### CROSS REFERENCE TO RELATED APPLICATION

The present disclosure is a continuation application of International Patent Application No. PCT/CN2022/139050, filed on Dec. 14, 2022, and claiming the priority to Chinese Application No. CN202211528780.8 filed on Nov. 30, 2022, the contents of all of which are incorporated herein by reference in their entirety for all purposes.

### TECHNICAL FIELD

The present application relates to the technical field of high-speed serial interface, and in particular to a high-speed parallel-to-serial conversion circuit.

### BACKGROUND

In recent years, with the continuous development of integrated circuits, the integration of chips has increased and the complexity of chips has increased. Especially for data transmission between high-speed converters (such as AD/DA) and other devices, the increase in input/output data volume and the increase in transmission speed, if the traditional parallel interface is used for transmission, will lead to an increase in the number of communication I/O port pins and parallel data offset and clock delay. Compared with the parallel interface, the JESD204B high-speed serial interface has the advantages of minimizing the number of communication I/O port pins between chips and reducing the number of data transmissions, so it is widely used. Because of the 8b/10b encoding method of the JESD204B protocol, in the process of parallel-to-serial conversion of parallel data, it is necessary to first use a parallel structure to convert the data into a data form of 2^{N} bit, and then use a tree structure to finally serialize the data.

### SUMMARY

A high-speed parallel-to-serial conversion circuit includes: a clock frequency division module, receiving an initial differential clock and performing frequency-dividing on the initial differential clock to obtain a plurality of frequency-divided clocks of different frequencies, wherein the frequency-divided clocks include a single-ended frequency-divided clock and a differential frequency-divided clock; a low-speed CMOS parallel-to-serial conversion module, connected to n bits of parallel data and a single-ended frequency-divided clock, and including N1 stages of CMOS parallel-to-serial conversion units, wherein the N1 stages of CMOS parallel-to-serial conversion units are cascaded in sequence and present a tree structure; under the control of the single-ended frequency-divided clock, N1 stages of parallel-to-serial conversion are performed on the n bits of parallel data to obtain n×2^{-N1} bits of parallel differential data; and a high-speed bipolar parallel-to-serial conversion module, connected to the n×2^{-N1} bits of parallel differential data and the differential frequency-divided clock, and including N2 stages of bipolar parallel-to-serial conversion units, wherein the N2 stages of bipolar parallel-to-serial conversion units are cascaded in sequence and present a tree structure; under the control of the differential frequency-divided clock, N2 stages of parallel-to-serial conversion are performed on the n×2^{-N1} bits of parallel differential data to obtain 1-bit parallel differential data, wherein, n=2N, N=N1+N2, both N1 and N2 are integers greater than or equal to 2.

In one or more embodiments, along a direction from a data input end of the low-speed CMOS parallel-to-serial conversion module to a data output end of the low-speed CMOS parallel-to-serial conversion module, an i-th stage of the CMOS parallel-to-serial conversion unit includes n×2ⁱ CMOS parallel-to-serial conversion subunits arranged in parallel, wherein i is an integer from 1 to N1.

In one or more embodiments, along the direction from the data input end of the low-speed CMOS parallel-to-serial conversion module to the data output end of the low-speed CMOS parallel-to-serial conversion module, in a j-th stage of the CMOS parallel-to-serial conversion unit, the CMOS parallel-to-serial conversion subunit includes a two-to-one selector and two D flip-flops, a clock input end of a first D flip-flop and a clock input end of a second D flip-flop are respectively connected to a (2j−1)-th single-ended frequency-divided clock, a positive data output end of the first D flip-flop and a positive data output end of the second D flip-flop are connected to two data input ends of the two-to-one selector in a one-to-one correspondence, a clock input end of the two-to-one selector is connected to a 2j-th single-ended frequency-divided clock, a data input end of the first D flip-flop and a data input end of the second D flip-flop are respectively used as data input ends of the CMOS parallel-to-serial conversion subunit, and a data output end of the two-to-one selector is used as a data output end of the CMOS parallel-to-serial conversion subunit, wherein j is an integer from 1 to N1−1.

In one or more embodiments, along the direction from the data input end of the low-speed CMOS parallel-to-serial conversion module to the data output end of the low-speed CMOS parallel-to-serial conversion module, in an N1-th stage of the CMOS parallel-to-serial conversion unit, the CMOS parallel-to-serial conversion subunit includes a two-to-one selector, an inverter, and three D flip-flops, a clock input end of the first D flip-flop and a clock input end of a second D flip-flop are respectively connected to a (2N1−1)-th single-ended frequency-divided clock, a positive data output end of a first D flip-flop and a positive data output end of a second D flip-flop are connected to two data input ends of the two-to-one selector in a one-to-one correspondence, a clock input end of the two-to-one selector is connected to a 2N1-th single-ended frequency-divided clock, a data output end of the two-to-one selector is connected to a data input end of a third D flip-flop, a clock input end of the third D flip-flop is connected to a (2N1+1)-th single-ended frequency-divided clock, a positive data output end of the third D flip-flop is connected to an input end of the inverter, and an input signal of the inverter and an output signal of the inverter constitute a bit of the n×2^{-N1} bits of parallel differential data.

In one or more embodiments, the frequency of a (2i−1)-th single-ended frequency-divided clock is the same as the frequency of a 2i-th single-ended frequency-divided clock, a ratio of the frequency of a 2i-th single-ended frequency-divided clock to the frequency of the initial differential clock is 2^{i-N}, and a ratio of the frequency of the (2N1+1)-th single-ended frequency-divided clock to the frequency of the initial differential clock is 2^{N1+1-N}.

In one or more embodiments, the two-to-one selector is a two-to-one selector with a CMOS structure, the D flip-flop is a D flip-flop with a CMOS structure, and the inverter is an inverter with a CMOS structure.

In one or more embodiments, along a direction from a data input end of the high-speed bipolar parallel-to-serial conversion module to a data output end of the high-speed bipolar parallel-to-serial conversion module, a k-th stage of the bipolar parallel-to-serial conversion unit includes n×2^{-(N1+i)} bipolar parallel-to-serial conversion subunits arranged in parallel, wherein k is an integer from 1 to N2.

In one or more embodiments, along the direction from the data input end of the high-speed bipolar parallel-to-serial conversion module to the data output end of the high-speed bipolar parallel-to-serial conversion module, in a m-th stage of the bipolar parallel-to-serial conversion unit, the bipolar parallel-to-serial conversion subunit includes a two-to-one selector and two D flip-flops, a clock input end of a first D flip-flop and a clock input end of a second D flip-flop are respectively connected to a (2m−1)-th differential frequency-divided clock, a positive data output end of the first D flip-flop and a positive data output end of the second D flip-flop are connected to two data input ends of the two-to-one selector in a one-to-one correspondence, a clock input end of the two-to-one selector is connected to a 2m-th differential frequency-divided clock, a data input end of the first D flip-flop and a data input end of the second D flip-flop are respectively used as a data input end of the bipolar parallel-to-serial conversion subunit, and a data output end of the two-to-one selector is used as a data output end of the bipolar parallel-to-serial conversion subunit, wherein m is an integer from 1 to N2-1.

In one or more embodiments, along the direction from the data input end of the high-speed bipolar parallel-to-serial conversion module to the data output end of the high-speed bipolar parallel-to-serial conversion module, in a N2-th stage of the bipolar parallel-to-serial conversion unit, the bipolar parallel-to-serial conversion subunit includes a two-to-one selector, a buffer, and two D flip-flops, a clock input end of a first D flip-flop and a clock input end of a second D flip-flop are respectively connected to a (2N2−1)-th differential frequency-divided clock, a positive data output end of the first D flip-flop is connected to an input end of the buffer, an output end of the buffer and a positive data output end of the second D flip-flop are connected to two data input ends of the two-to-one selector in a one-to-one correspondence, a clock input end of the two-to-one selector is connected to a 2N2-th differential frequency-divided clock, and a data output end of the two-to-one selector is used as a data output end of the bipolar parallel-to-serial conversion subunit and outputs the 1-bit parallel differential data.

In one or more embodiments, the frequency of a (2k−1)-th differential frequency-divided clock is the same as the frequency of a 2k-th differential frequency-divided clock, and a ratio of the frequency of a 2k-th differential frequency-divided clock to the frequency of the initial differential clock is 2^{k+N1-N}.

In one or more embodiments, the two-to-one selector is a two-to-one selector with a bipolar structure, the D flip-flop is a D flip-flop with a bipolar structure, and the buffer is a buffer with a bipolar structure.

In one or more embodiments, the two-to-one selector is a two-to-one selector with a differential structure, the D flip-flop is a D flip-flop with a differential structure, and the buffer is a buffer with a differential structure.

### BRIEF DESCRIPTION OF DRAWINGS

FIG. 1 shows a structural block diagram of a high-speed parallel-to-serial conversion circuit in the present application.

FIG. 2 shows a circuit diagram of a CMOS parallel-to-serial conversion subunit in an input stage and an intermediate stage of a low-speed CMOS parallel-to-serial conversion module in FIG. 1.

FIG. 3 shows a circuit diagram of a CMOS parallel-to-serial conversion subunit in an output stage of a low-speed CMOS parallel-to-serial conversion module in FIG. 1.

FIG. 4 shows a circuit diagram of a bipolar parallel-to-serial conversion subunit in an input stage and an intermediate stage of a high-speed bipolar parallel-to-serial conversion module in FIG. 1.

FIG. 5 shows a circuit diagram of a bipolar parallel-to-serial conversion subunit in an output stage of a high-speed bipolar parallel-to-serial conversion module in FIG. 1.

FIG. 6 shows a timing diagram of a serial-to-parallel conversion circuit without a buffer Td added thereto.

FIG. 7 shows a timing diagram of a serial-to-parallel conversion circuit with a buffer Td added thereto.

FIG. 8 shows a circuit diagram of a 32-bit high-speed parallel-to-serial conversion circuit in an exemplary embodiment of the present application.

FIG. 9A shows a circuit diagram of a low-speed CMOS parallel-to-serial conversion module in FIG. 8.

FIG. 9B shows a circuit diagram of a high-speed bipolar parallel-to-serial conversion module in FIG. 8.

### DESCRIPTION OF EMBODIMENTS

The following describes the embodiments of the present application through specific examples, and those skilled in the art can easily understand other advantages and effects of the present application from the contents disclosed in this specification. The present application can also be implemented or applied through other different specific embodiments, and the details in this specification can also be modified or changed in various ways based on different viewpoints and applications without departing from the spirit of the present application.

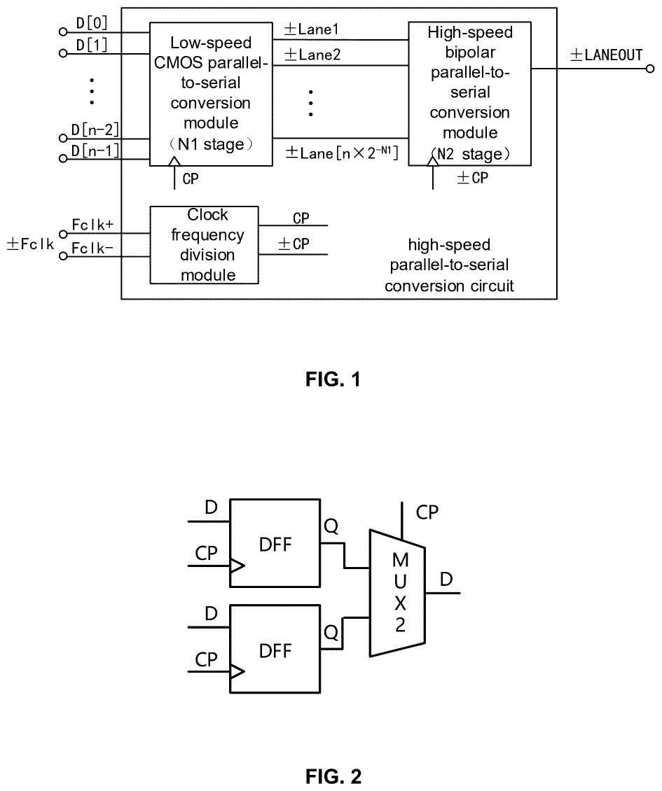

Please refer to FIGS. 1 to 9B. It should be noted that the diagrams provided in this embodiment only illustrate the basic concept of the present application in a schematic manner, so the diagrams only show the components related to the present application rather than drawing according to the number, shape, and size of the components in actual implementation. The type, quantity, and scale of each component in actual implementation can be changed at will, and the component layout type may also be more complicated. The structure, scale, size, etc. shown in the drawings attached to this specification are only used to match the content disclosed in the specification for people familiar with this technology to understand and read and are not used to limit the limiting conditions that the present application can be implemented, so they have no technical substantive significance. Any modification of the structure, change of the proportional relationship, or adjustment of the size should still fall within the scope of the technical content disclosed by the present application without affecting the effect that the present application can produce and the purpose that can be achieved.

However, the parallel circuit structure can only be applied to high-speed systems when the number of bits is small, while the tree circuit structure is not limited by the number of data bits. In addition, the JESD204B standard protocol has high requirements for digital logic and is difficult to manufacture using bipolar processes. However, the performance speed of bipolar devices is higher than that of CMOS devices under the same size process, so the traditional CMOS parallel-to-serial conversion circuit is limited. For faster and more efficient chip communication, the proposal of ESIstream protocol effectively solves the above problems. The ESIstream protocol provides an efficient and high-speed serial interface based on 14b/16b encoding. Its core digital logic is simple and easy to implement in BiCMOS process.

For the efficient and high-speed serial interface of the ESIstream14b/16b protocol, bipolar devices are needed to achieve high speed, but bipolar devices have high power consumption, small size and area, and low integration. To reduce power consumption and process implementation difficulty, CMOS devices must be used, but CMOS devices have low speed, large size and area, and high integration.

Therefore, there is an urgent need for a technical solution of a high-speed parallel-to-serial conversion suitable for the ESIstream14b/16b protocol that effectively takes into account speed, process implementation difficulty, power consumption, and area.

In view of the shortcomings of the conventional technique mentioned above, the purpose of the present application is to provide a technical solution of a high-speed parallel-to-serial conversion, which combines CMOS devices and bipolar devices to design a parallel-to-serial conversion circuit, where the low-speed part is implemented by CMOS devices, and the high-speed part is implemented by bipolar devices, so as to comprehensively reduce the power consumption and area of the parallel-to-serial conversion circuit and improve the data transmission rate.

As described above, the inventors have found that the structure of the traditional parallel-to-serial conversion circuit has the following defects.

1. Due to the 10-bit parallel encoding data of the JESD204B protocol, the structure of the parallel-to-serial conversion circuit cannot fully adopt the tree structure suitable for high-speed occasions, and the speed of the parallel-to-serial conversion circuit is limited.

2. For higher-speed chips, the interface standard of the traditional parallel-to-serial conversion circuit is too complex. To achieve higher performance, a large amount of digital logic is required, which cannot give full play to the advantages of CMOS devices and bipolar devices, resulting in a complex structure of the parallel-to-serial conversion circuit and limited speed.

Based on this, the present application provides a technical solution of a high-speed parallel-to-serial conversion: a parallel-to-serial conversion circuit is designed by combining CMOS devices and bipolar devices, the low-speed part is implemented by CMOS devices, and the high-speed part is implemented by bipolar devices, so as to comprehensively reduce the power consumption and area of the parallel-to-serial conversion circuit and improve the data transmission rate; In addition, both the low-speed part and the high-speed part adopt a tree structure to further improve the data transmission rate.

As shown in FIG. 1, the present application provides a high-speed parallel-to-serial conversion circuit, which includes: a clock frequency division module receiving an initial differential clock±Folk and dividing the initial differential clock±Folk to obtain a plurality of frequency-divided clocks of different frequencies, wherein the frequency-divided clocks include a single-ended frequency-divided clock CP and a differential frequency-divided clock±CP; a low-speed CMOS parallel-to-serial conversion module connected to n bits of parallel data D[0]˜D [n-1] and the single-ended frequency-divided clock CP, wherein the low-speed CMOS parallel-to-serial conversion module includes N1 stages of CMOS parallel-to-serial conversion units that are sequentially cascaded and present a tree structure; under the control of the single-ended frequency-divided clock CP, the n bits of parallel data D[0]˜D [n−1] are subjected to N1 stages of parallel-to-serial conversion to obtain n×2^{-N1} bits of parallel differential data±lane1 to ±lane [n×2^{-N1}]; and a high-speed bipolar parallel-to-serial conversion module connected to the n×2^{-N1} bits of parallel differential data±lane1˜±lane [n×2^{-N1}] and the differential frequency-divided clock ±CP, wherein the high-speed bipolar parallel-to-serial conversion module includes N2 stages of bipolar parallel-to-serial conversion units which are sequentially cascaded and present a tree structure; under the control of the differential frequency-divided clock±CP, the n×2^{-N1} bits of parallel differential data±lane1 to ±lane [n×2-N1] are subjected to N2 stages of parallel-to-serial conversion to obtain 1-bit parallel differential data±LANEOUT, wherein, n=2^{N}, N=N1+N2, N1 and N2 are integers greater than or equal to 2.

In one or more embodiments, the clock frequency division module divides the initial differential clock±Folk input from the outside, whose clock frequency is Folk. The single-ended frequency-divided clock CP and the differential frequency-divided clock±CP are generated by a divider inside the clock frequency division module for use at each stage of the parallel-to-serial conversion circuit. For example, the single-ended frequency-divided clock CP includes CP1, CP2, CP3, CP4, and CP5. The clock frequencies of the single-ended frequency-divided clocks CP1, CP2, CP3, CP4 and CP5 are 1/16Fclk, 1/16Folk, 1/8Fclk, 1/8Fclk, and 1/4Fclk, respectively. The differential frequency-divided clock±CP includes ±CP6, ±CP7, ±CP8, ±CP9, ±CP10, and ±CP11. The clock frequencies of the differential frequency-divided clocks+CP6, ±CP7, ±CP8, ±CP9, ±CP10, and ±CP11 are 1/4Fclk, 1/4Fclk, 1/2Fclk, 1/2Fclk, Folk and Folk, respectively.

It should be noted that the clock frequency division module can achieve multiple frequency division processing through any superposition, combination, and cascade of internal frequency dividers, not limited to divided-by-2 clock, divided-by-4 clock, divided-by-8 clock, etc., which can be selected according to actual needs. For details, please refer to the existing technology, and no limitation is made here.

In one or more embodiments, in the low-speed CMOS parallel-serial conversion module, along the direction from a data input end of the low-speed CMOS parallel-serial conversion module to a data output end of the low-speed CMOS parallel-serial conversion module, the i-th stage of CMOS parallel-serial conversion unit includes n×2⁻ⁱ CMOS parallel-serial conversion subunits arranged in parallel, where i is an integer from 1 to N1.

In one or more embodiments, in the low-speed CMOS parallel-serial conversion module, along the direction from a data input end of the low-speed CMOS parallel-serial conversion module to a data output end of the low-speed CMOS parallel-serial conversion module, except for the N1-th stage of CMOS parallel-serial conversion unit, the structures of the CMOS parallel-serial conversion subunits in the first N1−1 stages of CMOS parallel-serial conversion units are the same, as shown in FIG. 2, that is, the structures of the CMOS parallel-serial conversion subunits in the input stage and in the intermediate stage of the entire low-speed CMOS parallel-serial conversion module are the same, and the number of CMOS parallel-serial conversion subunits from the previous stage of CMOS parallel-serial conversion unit to the subsequent stage of CMOS parallel-serial conversion unit is reduced by a common ratio of 1/2.

In one or more embodiments, as shown in FIG. 2, in the j-th stage of CMOS parallel-to-serial conversion unit, the CMOS parallel-to-serial conversion subunit includes a two-to-one selector MUX2 and two D flip-flops DFF, the clock input end CP of the first D flip-flop DFF and the clock input end CP of the second D flip-flop DFF are respectively connected to the (2j−1)-th single-ended frequency-divided clock CP (2j−1) (not shown in the figure), the positive data output end Q of the first D flip-flop DFF and the positive data output end Q of the second D flip-flop DFF are connected to two data input ends of the two-to-one selector MUX2 in a one-to-one correspondence, the clock input end CP of the two-to-one selector MUX2 is connected to the 2j-th single-ended frequency-divided clock CP (2j) (not shown in the figure), the data input end D of the first D flip-flop DFF and the data input end D of the second D flip-flop DFF are respectively used as the data input ends of the CMOS parallel-to-serial conversion subunit, and the data output end D of the two-to-one selector MUX2 is used as the data output end of the CMOS parallel-to-serial conversion subunit, where j is an integer from 1 to N1−1.

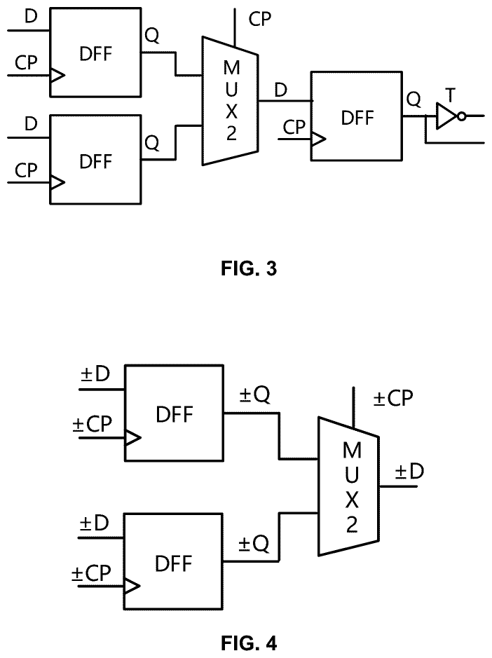

In one or more embodiments, in the low-speed CMOS parallel-to-serial conversion module, the structure of the N1-th stage of CMOS parallel-to-serial conversion unit is slightly different from the structures of the previous N1−1 stages of CMOS parallel-to-serial conversion units, because after completing the serialization function, it is also necessary to convert the full-swing single-ended output into a fully differential output for use by subsequent bipolar circuits. The structures of each CMOS parallel-to-serial conversion subunit in the N1-th stage of CMOS parallel-to-serial conversion unit are the same, as shown in FIG. 3.

In one or more embodiments, as shown in FIG. 3, along the direction from the data input end of the low-speed CMOS parallel-to-serial conversion module to the data output end of the low-speed CMOS parallel-to-serial conversion module, in the N1-th stage of CMOS parallel-to-serial conversion unit, the CMOS parallel-to-serial conversion subunit includes a two-to-one selector MUX2, an inverter T, and three D flip-flops DFF, a clock input end CP of the first D flip-flop DFF and a clock input end CP of the second D flip-flop DFF are respectively connected to the (2N1−1)-th single-ended frequency-divided clock CP (2N1−1) (not shown in the figure), and the positive data output end Q of the first D flip-flop DFF and the positive data output end Q of the second D flip-flop DFF are connected to two data input ends of the two-to-one selector MUX2 in one-to-one correspondence, the clock input end CP of the two-to-one selector MUX2 is connected to the 2N1-th single-ended frequency-divided clock CP (2N1) (not shown in the figure), the data output end D of the two-to-one selector MUX2 is connected to the data input end of the third D flip-flop DFF, the clock input end CP of the third D flip-flop DFF is connected to the (2N1+1)-th single-ended frequency-divided clock CP (2N1+1) (not shown in the figure), the positive data output end Q of the third D flip-flop DFF is connected to the input end of the inverter T, and the input signal of the inverter T and the output signal of the inverter T constitute one bit of the n×2^{-N1} bits of parallel differential data ±lane1 to ±lane [n×2-N1].

In addition, the frequency of the (2i−1)-th single-ended frequency-divided clock CP (2i-1) is the same as the frequency of the 2i-th single-ended frequency-divided clock CP (2i), the ratio of the frequency of the 2i-th single-ended frequency-divided clock CP (2i) to the frequency of the initial differential clock±Folk is 2i−N, and the ratio of the frequency of the (2N1+1)-th single-ended frequency-divided clock CP (2N1+1) to the frequency of the initial differential clock ±Fclk is 2^{N1+1-N}.

As shown in FIGS. 2 and 3, each stage of the CMOS parallel-to-serial conversion subunit in the low-speed CMOS parallel-to-serial conversion module is a single-ended structure. In each stage of the CMOS parallel-to-serial conversion subunit, the input clocks of the D flip-flop DFF and the two-to-one selector MUX2 correspond to single-ended clocks with the same frequency; and the D flip-flop DFF samples at the rising edge of the clock and temporarily stores the data once, and the two-to-one selector MUX2 selects the data at the high and low levels, respectively, thereby combining two groups of parallel data into one group of serial data.

It should be emphasized that all stages of CMOS parallel-to-serial conversion subunits in the low-speed CMOS parallel-to-serial conversion module have a CMOS structure and are formed using CMOS processes or devices. That is to say, in the low-speed CMOS parallel-to-serial conversion module, the two-to-one selector MUX2 is a two-to-one selector having a CMOS structure, the D flip-flop DFF is a D flip-flop having a CMOS structure, and the inverter T is an inverter having a CMOS structure. The specific process structure of the corresponding CMOS device can be found in the conventional technique and will not be repeated here.

Similarly, in the high-speed bipolar parallel-serial conversion module, along the direction from the data input end of the high-speed bipolar parallel-serial conversion module to the data output end of the high-speed bipolar parallel-serial conversion module, the k-th stage bipolar parallel-serial conversion unit includes n×2^{-(N1+i)} bipolar parallel-serial conversion subunits arranged in parallel, where k is an integer from 1 to N2.

In one or more embodiments, in the high-speed bipolar parallel-serial conversion module, along the direction from the data input end of the high-speed bipolar parallel-serial conversion module to the data output end of the high-speed bipolar parallel-serial conversion module, except for the N2-th stage of bipolar parallel-serial conversion unit, the structures of the bipolar parallel-serial conversion subunits in the first N2-1 stages of bipolar parallel-serial conversion units are the same, as shown in FIG. 4, that is, the structures of the bipolar parallel-serial conversion subunits in the input stage and the intermediate stage of the entire high-speed bipolar parallel-serial conversion module are the same, and the number of bipolar parallel-serial conversion subunits from the previous stage of bipolar parallel-serial conversion unit to the subsequent stage of bipolar parallel-serial conversion unit is reduced by a common ratio of 1/2.

In one or more embodiments, as shown in FIG. 4, in the m-th stage of bipolar parallel-to-serial conversion unit, the bipolar parallel-to-serial conversion subunit includes a two-to-one selector MUX2 and two D flip-flops DFF, the clock input end ±CP of the first D flip-flop DFF and the clock input end±CP of the second D flip-flop DFF are respectively connected to the (2m−1)-th differential frequency-divided clock ±CP (2m−1) (not shown in the figure), the positive data output end±Q of the first D flip-flop DFF and the positive data output end±Q of the second D flip-flop DFF are connected to two data input ends of the two-to-one selector MUX2 in a one-to-one correspondence, the clock input end±CP of the two-to-one selector MUX2 is connected to the 2m-th differential frequency-divided clock±CP (2m) (not shown in the figure), the data input end±D of the first D flip-flop DFF and the data input end ±D of the second D flip-flop DFF are respectively used as data input ends of the bipolar parallel-to-serial conversion subunit, and the data output end±D of the two-to-one selector MUX2 is used as the data output end of the bipolar parallel-to-serial conversion subunit, where m is an integer from 1 to N2−1.

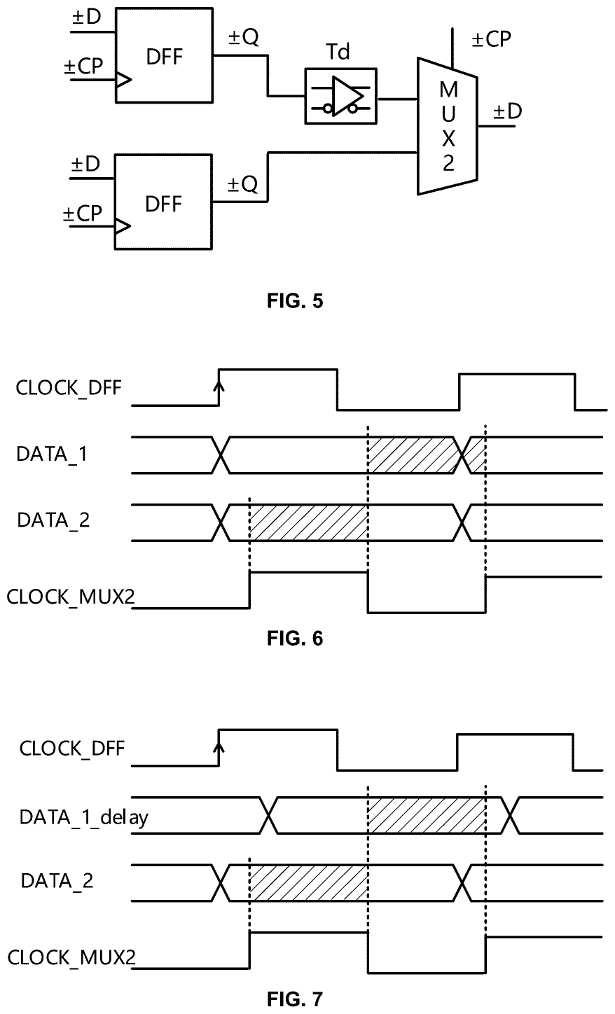

In one or more embodiments, in the high-speed bipolar parallel-to-serial conversion module, the structure of the N2-th stage of bipolar parallel-to-serial conversion unit is slightly different from the structures of the first N2−1 stages of bipolar parallel-to-serial conversion. Because it is the last stage of the high-speed bipolar parallel-to-serial conversion module, the parallel-to-serial conversion circuit has the highest final output data rate and strict timing requirements. A buffer Td is added in the N2-th stage to play a delay role, so as to effectively reduce the jitter of the serialized data. The N2-th stage of bipolar parallel-to-serial conversion unit includes only one bipolar parallel-to-serial conversion subunit, and its structure is shown in FIG. 5.

In one or more embodiments, as shown in FIG. 5, along the direction from the data input end of the high-speed bipolar parallel-to-serial conversion module to the data output end of the high-speed bipolar parallel-to-serial conversion module, in the N2-th stage of bipolar parallel-to-serial conversion unit, the bipolar parallel-to-serial conversion subunit includes a two-to-one selector MUX2, a buffer Td, and two D flip-flops DFF, the clock input end±CP of the first D flip-flop DFF and the clock input end±CP of the second D flip-flop DFF are respectively connected to the (2N2−1)-st differential frequency-divided clock±CP (2N2−1) (not shown in the figure), and the positive data output end±Q of the first D flip-flop DFF is connected to the input end of the buffer Td, the output end of the buffer Td and the positive data output end±Q of the second D flip-flop DFF are connected one-to-one with two data input ends of the two-to-one selector MUX2 in a one-to-one correspondence, the clock input end±CP of the two-to-one selector MUX2 is connected to the 2N2-th differential frequency-divided clock±CP (2N2) (not shown in the figure), and the data output end±D of the two-to-one selector MUX2 is used as the data output end of the bipolar parallel-to-serial conversion subunit and outputs 1-bit parallel differential data±LANEOUT (not shown in the figure).

The frequency of the (2k−1)-th differential frequency-divided clock±CP (2k−1) is the same as the frequency of the 2k-th differential frequency-divided clock ±CP (2k), and the ratio of the frequency of the 2k-th differential frequency-divided clock±CP (2k) to the frequency of the initial differential clock±Folk is 2^{k+N1-N}.

As shown in FIGS. 4 and 5, each stage of bipolar parallel-to-serial conversion subunit in the high-speed bipolar parallel-to-serial conversion module is a differential structure, the two-to-one selector MUX2 is a two-to-one selector with a differential structure, the D flip-flop DFF is a D flip-flop with a differential structure, and the buffer Td is a buffer with a differential structure; in each stage of bipolar parallel-to-serial conversion subunit, the input clocks of the D flip-flop DFF and the two-to-one selector MUX2 correspond to differential clocks with the same frequency; and the D flip-flop DFF samples at the rising edge of the clock and temporarily stores the data once, and the two-to-one selector MUX2 selects the data at the high and low levels respectively, thereby combining two groups of parallel data into one group of serial data.

It should be emphasized that all stages of bipolar parallel-to-serial conversion subunits in the high-speed bipolar parallel-to-serial conversion module are bipolar structures and are formed using bipolar processes or devices. That is to say, in the high-speed bipolar parallel-to-serial conversion module, the two-to-one selector MUX2 is a two-to-one selector with a bipolar structure, the D flip-flop DFF is a D flip-flop with a bipolar structure, and the buffer Td is a buffer with a bipolar structure. The specific process structure of the corresponding bipolar devices can be found in the conventional technique and will not be repeated here.

In addition, in order to verify the technical effect of buffer Td, the technical solutions without buffer Td and with buffer Td are compared, and the timing diagrams of the corresponding serial-to-parallel conversion circuits are shown in FIGS. 6 and 7 respectively; FIG. 6 shows the timing diagram of the serial-to-parallel conversion circuit without buffer Td. As shown in FIG. 6, in order to ensure data integrity at ultra-high speed, it is necessary to reserve a certain time before synthesizing DATA_2, which will inevitably lead to the problem of data jump in DATA_1 at the end of the CLOCK_MUX clock; FIG. 7 shows the timing diagram of the serial-to-parallel conversion circuit with buffer Td added. After delaying DATA_1 for a certain period of time and then serializing it, DATA_1 and DATA_2 can have sufficient redundant time, which effectively reduces the probability of data jump.

In one or more embodiments, as shown in FIGS. 1 to 5, the working principle of the entire high-speed parallel-to-serial conversion circuit is as follows.

1) The initial differential clock±Folk is input to the clock frequency division module, and the clock frequency division module divides the initial differential clock ±Folk to obtain a single-ended frequency-divided clock CP and a differential frequency-divided clock±CP of multiple frequencies for use at all stages of the parallel-to-serial conversion circuit.

2) The n bits of parallel data D[0] to D [n−1] are input to the low-speed CMOS parallel-to-serial conversion module; the N1-stage CMOS parallel-to-serial conversion units are cascaded in sequence and have a tree structure, the parallel-to-serial conversion rate of the first N1 stages is low; the corresponding parallel-to-serial conversion unit is implemented using a CMOS circuit, its working clock frequency increases exponentially from the input end to the output end; the n bits of parallel data D[0] to D [n−1] are subjected to N1 stages of parallel-to-serial conversion, and then subjected to an operation of conversion from the single-ended into the differential to obtain n×2^{-N1} bits of parallel differential data±lane1 to ±lane [n×2^{-N1}].

3) The n×2^{-N1} bits of parallel differential data±lane1 to ±lane [n×2^{-N1}] are input to the high-speed bipolar parallel-to-serial conversion module; the N2 stages of bipolar parallel-to-serial conversion units are cascaded in sequence and have a tree structure; the parallel-to-serial conversion rate of the latter N2 stages increases exponentially; the corresponding parallel-to-serial conversion units are implemented using bipolar circuits, and their operating clock frequencies also increase exponentially; the n×2^{-N1} bits of parallel differential data±lane1 to ±lane [n×2^{-N1}] are subjected to N2 stages of parallel-to-serial conversion, and finally 1-bit parallel differential data±LANEOUT is obtained.

4) The entire high-speed parallel-to-serial conversion circuit combines CMOS devices and bipolar devices; the low-speed part is implemented with CMOS devices, and the high-speed part is implemented with bipolar devices; through the combination of the two, the power consumption area and rate performance are effectively balanced; in addition, the low-speed CMOS parallel-to-serial conversion module and the high-speed bipolar parallel-to-serial conversion module all use a tree structure, which further improves the data transmission rate.

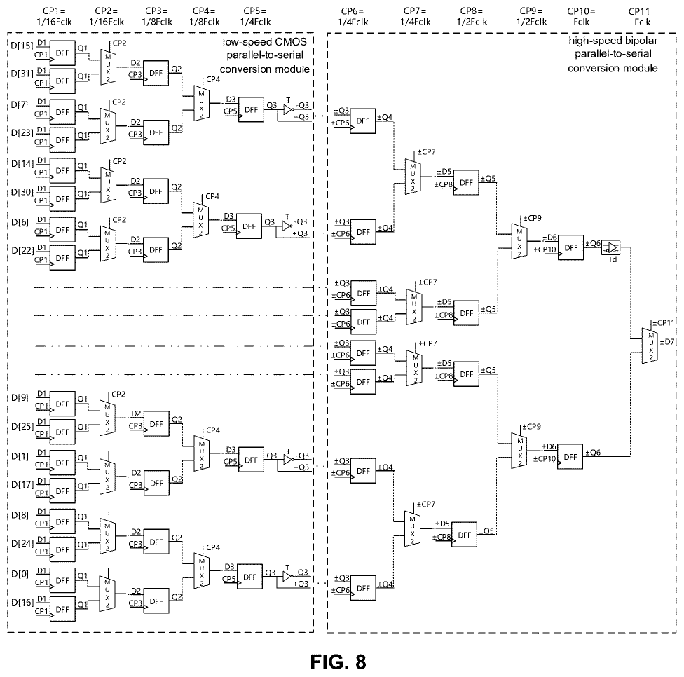

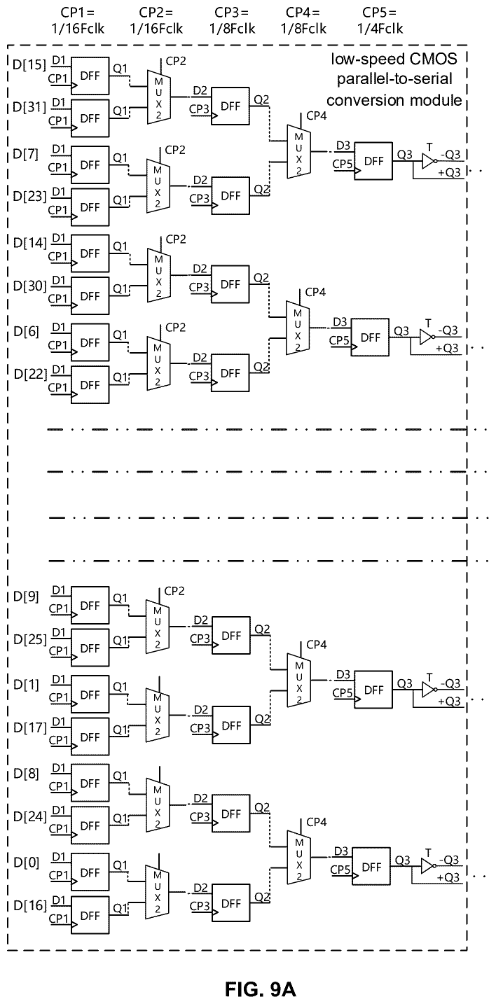

In an optional embodiment of the present application, n=32, N=5, that is, the high-speed parallel-to-serial conversion circuit is a 32-bit high-speed parallel-to-serial conversion circuit, as shown in FIG. 8, 32 bits of parallel data D[0] to D[31] are connected to the input end of the high-speed parallel-to-serial conversion circuit in the order shown in the figure, the high-speed parallel-to-serial conversion circuit has a 32:1 five-stage tree structure, the working clock of the parallel-to-serial conversion circuit is provided by a clock frequency division module, the low-speed CMOS parallel-to-serial conversion module uses a full-swing single-ended clock, and the high-speed bipolar parallel-to-serial conversion module uses a fully differential clock, and the specific clock frequency is shown in the figure as CP1-CP11.

In one or more embodiments, as shown in FIG. 8, the working principle of the parallel-to-serial conversion circuit of the five-stage tree structure is as follows:
32 bits of parallel data D[0] to D[31] are sampled by first D flip-flops DFF to generate 32 sets of intermediate data Q1, and two-to-one selectors MUX1 perform a first serialization to generate 16 sets of parallel data D2;
the 16 sets of parallel data D2 pass through second D flip-flops DFF to generate 16 sets of intermediate data Q2, and two-to-one selectors MUX2 perform a second serialization to generate 8 sets of parallel data D3;
the 8 sets of parallel data D3 pass through third D flip-flops DFF, and then pass through inverters T, the inverters T perform the data conversion from single-end to double-end, such that 8 sets of parallel differential data±Q3 (i.e. Lane 1 to Lane 8) are output to the subsequent bipolar circuit;
the 8 sets of parallel differential data±Q3 pass through fourth D flip-flops DFF to generate 8 sets of intermediate data±Q4, and two-to-one selectors MUX2 perform a third serialization to generate 4 sets of parallel differential data±D5;
the 4 sets of parallel differential data±D5 pass through the fifth D flip-flops DFF to generate 4 sets of intermediate data±Q5, and two-to-one selectors MUX2 perform a fourth serialization to generate 2 sets of parallel differential data±D6;
the parallel differential data±D6 passes through the sixth D flip-flops DFF to generate 2 sets of intermediate data±Q6; one set of data is delayed by a buffer Td and then serialized for the fifth time by the two-to-one selector MUX2 to generate 1-bit output differential data±D7 (i.e., ±LANEOUT).

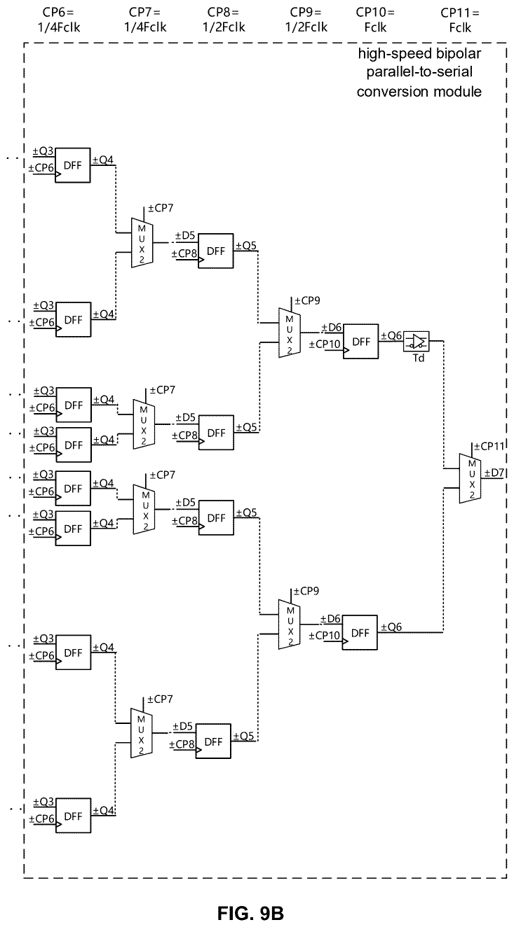

In order to further verify the above advantages of the present application, a parallel-to-serial conversion circuit structure as shown in FIG. 8 is used to simulate 32-bit conversion from parallel data to serial data under BiCMOS technology. FIG. 9A is the left portion in FIG. 8 and FIG. 9B is the right portion in FIG. 8. When the initial differential clock±Folk of the external input is 6.4 GHz and 8 GHZ, the input rate of the parallel data is 0.4 GHz and 0.5 GHZ, and the output rate of the serialized data is 12.8 GHz and 16 GHz. Therefore, the high-speed parallel-to-serial conversion circuit structure proposed in the present application is suitable for the ESIstream 14b/16b encoding protocol and still has good serialization performance when the serialized output data is 12.8 GHz and 16 GHz. The high-speed parallel-to-serial conversion circuit shown in the present application achieves a good balance between consumption of power and area and speed performance.

As stated above, the high-speed parallel-to-serial conversion circuit provided by the present application has at least the following beneficial effects.

The parallel-to-serial conversion module is designed by combining “clock frequency division module, low-speed CMOS parallel-to-serial conversion module, and high-speed bipolar parallel-to-serial conversion module”. The low-speed CMOS parallel-to-serial conversion module includes N1 stages of CMOS parallel-to-serial conversion units that are cascaded in sequence and present a tree structure, and the high-speed bipolar parallel-to-serial conversion module includes N2 stages of bipolar parallel-to-serial conversion units that are cascaded in sequence and present a tree structure. That is to say, the low-speed part is implemented by CMOS devices, and the high-speed part is implemented by bipolar devices. Through the combination of the two, the data transmission rate can be comprehensively improved, and the power consumption and area of the parallel-to-serial conversion circuit can be reduced. In addition, the low-speed CMOS parallel-to-serial conversion module and the high-speed bipolar parallel-to-serial conversion module both use a tree structure, which further improves the data transmission rate.

The above embodiments are merely illustrative of the principles and effects of the present application, and are not intended to limit the present application. Anyone familiar with the art may modify or alter the above embodiments without departing from the spirit and scope of the present application. Therefore, all equivalent modifications or alterations made by a person of ordinary skill in the art without departing from the spirit and technical concept disclosed by the present application shall still be covered by the claims of the present application.

What is claimed is:

1. A high-speed parallel-to-serial conversion circuit, comprising:
a clock frequency division module, receiving an initial differential clock and performing frequency-dividing on the initial differential clock to obtain a plurality of frequency-divided clocks of different frequencies, wherein the frequency-divided clock includes a single-ended frequency-divided clock and a differential frequency-divided clock;
a low-speed CMOS parallel-to-serial conversion module, connected to n bits of parallel data and the single-ended frequency-divided clock, and the low-speed CMOS parallel-to-serial conversion module including N1 stages of CMOS parallel-to-serial conversion units, wherein the N1 stages of CMOS parallel-to-serial conversion units are cascaded in sequence to form a tree structure; under a control of the single-ended frequency-divided clock, N1 stages of parallel-to-serial conversion are performed on the n bits of parallel data to obtain n×2^{-N1} bits of parallel differential data; and
a high-speed bipolar parallel-to-serial conversion module, connected to the n×2^{-N1} bits of parallel differential data and the differential frequency-divided clock, and the high-speed bipolar parallel-to-serial conversion module including N2 stages of bipolar parallel-to-serial conversion units, wherein the N2 stages of bipolar parallel-to-serial conversion units are cascaded in sequence to form a tree structure; under a control of the differential frequency-divided clock, N2 stages of parallel-to-serial conversion are performed on the n×2^{-N1} bits of parallel differential data to obtain 1-bit parallel differential data,
wherein, n=2N, N=N1+N2, both N1 and N2 are integers greater than or equal to 2.

2. The high-speed parallel-to-serial conversion circuit according to claim 1, wherein along a direction from a data input end of the low-speed CMOS parallel-to-serial conversion module to a data output end of the low-speed CMOS parallel-to-serial conversion module, a i-th stage of the CMOS parallel-to-serial conversion unit includes n×2⁻ⁱ CMOS parallel-to-serial conversion subunits arranged in parallel, wherein i is an integer from 1 to N1.

3. The high-speed parallel-to-serial conversion circuit according to claim 2, wherein along the direction from the data input end of the low-speed CMOS parallel-to-serial conversion module to the data output end of the low-speed CMOS parallel-to-serial conversion module, in a j-th stage of the CMOS parallel-to-serial conversion unit, the CMOS parallel-to-serial conversion subunit includes a two-to-one selector and two D flip-flops, a clock input end of a first D flip-flop and a clock input end of a second D flip-flop are respectively connected to a (2j−1)-th single-ended frequency-divided clock, a positive data output end of the first D flip-flop and a positive data output end of the second D flip-flop are connected to two data input ends of the two-to-one selector in a one-to-one correspondence, a clock input end of the two-to-one selector is connected to a 2j-th single-ended frequency-divided clock, a data input end of the first D flip-flop and a data input end of the second D flip-flop are respectively used as data input ends of the CMOS parallel-to-serial conversion subunit, and a data output end of the two-to-one selector is used as a data output end of the CMOS parallel-to-serial conversion subunit, wherein j is an integer from 1 to N1−1.

4. The high-speed parallel-to-serial conversion circuit according to claim 3, wherein a frequency of a (2i−1)-th single-ended frequency-divided clock is the same as a frequency of a 2i-th single-ended frequency-divided clock, a ratio of the frequency of the 2i-th single-ended frequency-divided clock to a frequency of the initial differential clock is 2i−N, and a ratio of a frequency of the (2N1+1)-th single-ended frequency-divided clock to the frequency of the initial differential clock is 2^{N1+1-N}.

5. The high-speed parallel-to-serial conversion circuit according to claim 3, wherein the two-to-one selector is a two-to-one selector with a CMOS structure, the D flip-flop is a D flip-flop with a CMOS structure.

6. The high-speed parallel-to-serial conversion circuit according to claim 2, wherein along the direction from the data input end of the low-speed CMOS parallel-to-serial conversion module to the data output end of the low-speed CMOS parallel-to-serial conversion module, in an N1-th stage of the CMOS parallel-to-serial conversion unit, the CMOS parallel-to-serial conversion subunit includes a two-to-one selector, an inverter, and three D flip-flops, a clock input end of a first D flip-flop and a clock input end of a second D flip-flop are respectively connected to a (2N1−1)-th single-ended frequency-divided clock, a positive data output end of the first D flip-flop and a positive data output end of the second D flip-flop are connected to two data input ends of the two-to-one selector in a one-to-one correspondence, a clock input end of the two-to-one selector is connected to a 2N1-th single-ended frequency-divided clock, a data output end of the two-to-one selector is connected to a data input end of a third D flip-flop, a clock input end of the third D flip-flop is connected to a (2N1+1)-th single-ended frequency-divided clock, a positive data output end of the third D flip-flop is connected to an input end of the inverter, and an input signal of the inverter and an output signal of the inverter constitute a bit of the n×2^{-N1} bits of parallel differential data.

7. The high-speed parallel-to-serial conversion circuit according to claim 6, wherein a frequency of a (2i−1)-th single-ended frequency-divided clock is the same as a frequency of a 2i-th single-ended frequency-divided clock, a ratio of the frequency of the 2i-th single-ended frequency-divided clock to a frequency of the initial differential clock is 2^{i-N}, and a ratio of a frequency of the (2N1+1)-th single-ended frequency-divided clock to the frequency of the initial differential clock is 2^{N1+1-N}.

8. The high-speed parallel-to-serial conversion circuit according to claim 6, wherein the two-to-one selector is a two-to-one selector with a CMOS structure, the D flip-flop is a D flip-flop with a CMOS structure, and the inverter is an inverter with a CMOS structure.

9. The high-speed parallel-to-serial conversion circuit according to claim 1, wherein along a direction from a data input end of the high-speed bipolar parallel-to-serial conversion module to a data output end of the high-speed bipolar parallel-to-serial conversion module, a k-th stage of the bipolar parallel-to-serial conversion unit includes n×2^{-(N1+i)} bipolar parallel-to-serial conversion subunits arranged in parallel, wherein k is an integer from 1 to N2.

10. The high-speed parallel-to-serial conversion circuit according to claim 9, wherein along the direction from the data input end of the high-speed bipolar parallel-to-serial conversion module to the data output end of the high-speed bipolar parallel-to-serial conversion module, in a m-th stage of the bipolar parallel-to-serial conversion unit, the bipolar parallel-to-serial conversion subunit includes a two-to-one selector and two D flip-flops, a clock input end of a first D flip-flop and a clock input end of a second D flip-flop are respectively connected to a (2m−1)-th differential frequency-divided clock, a positive data output end of the first D flip-flop and a positive data output end of the second D flip-flop are connected to two data input ends of the two-to-one selector in a one-to-one correspondence, a clock input end of the two-to-one selector is connected to a 2m-th differential frequency-divided clock, a data input end of the first D flip-flop and a data input end of the second D flip-flop are respectively used as a data input end of the bipolar parallel-to-serial conversion subunit, and a data output end of the two-to-one selector is used as a data output end of the bipolar parallel-to-serial conversion subunit, wherein m is an integer from 1 to N2−1.

11. The high-speed parallel-to-serial conversion circuit according to claim 10, wherein a frequency of a (2k−1)-th differential frequency-divided clock is the same as a frequency of a 2k-th differential frequency-divided clock, and a ratio of the frequency of the 2k-th differential frequency-divided clock to a frequency of the initial differential clock is 2^{k+N1-N}.

12. The high-speed parallel-to-serial conversion circuit according to claim 10, wherein the two-to-one selector is a two-to-one selector with a bipolar structure, the D flip-flop is a D flip-flop with a bipolar structure.

13. The high-speed parallel-to-serial conversion circuit according to claim 9, wherein along the direction from the data input end of the high-speed bipolar parallel-to-serial conversion module to the data output end of the high-speed bipolar parallel-to-serial conversion module, in a N2-th stage of the bipolar parallel-to-serial conversion unit, the bipolar parallel-to-serial conversion subunit includes a two-to-one selector, a buffer, and two D flip-flops, a clock input end of a first D flip-flop and a clock input end of a second D flip-flop are respectively connected to a (2N2−1)-th differential frequency-divided clock, a positive data output end of the first D flip-flop is connected to an input end of the buffer, an output end of the buffer and a positive data output end of the second D flip-flop are connected to two data input ends of the two-to-one selector in a one-to-one correspondence, a clock input end of the two-to-one selector is connected to a 2N2-th differential frequency-divided clock, and a data output end of the two-to-one selector is used as a data output end of the bipolar parallel-to-serial conversion subunit and outputs the 1-bit parallel differential data.

14. The high-speed parallel-to-serial conversion circuit according to claim 13, wherein a frequency of a (2k−1)-th differential frequency-divided clock is the same as a frequency of a 2k-th differential frequency-divided clock, and a ratio of the frequency of the 2k-th differential frequency-divided clock to a frequency of the initial differential clock is 2^{k+N1-N}.

15. The high-speed parallel-to-serial conversion circuit according to claim 13, wherein the two-to-one selector is a two-to-one selector with a bipolar structure, the D flip-flop is a D flip-flop with a bipolar structure, and the buffer is a buffer with a bipolar structure.

16. The high-speed parallel-to-serial conversion circuit according to claim 15, wherein the two-to-one selector is a two-to-one selector with a differential structure, the D flip-flop is a D flip-flop with a differential structure, and the buffer is a buffer with a differential structure.
